(19) United States
(12) Patent Application Publication
(10) Pub. No.: US 2007/0158666 A1
(43) Pub. Date: Jul. 12, 2007

(54) Backlight Unit

(76) Inventors: Chuan-Pei Yu, I-Lan Hsien (TW); Rui-Yong Li, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/307,592

(22) Filed: Feb. 14, 2006

(30) Foreign Application Priority Data
Jan. 4, 2006 (TW) 095100365

(51) Int. Cl. H01L 33/00

(52) U.S. Cl. 257/98

(57) ABSTRACT

A backlight unit includes a light guide plate having a light-incidence plane and a light-exit plane and at least a light emitting diode (LED) mixing package located in proximity to the light-incidence plane for providing lights to the backlight unit. The LED mixing package includes at least a first color LED chip, at least a first color compensation film corresponding to the first color LED chip, at least a second color LED chip, and at least a second color compensation film corresponding to the second color LED chip, in which the first color compensation film and the second color compensation film are located on the light-incidence plane of the backlight unit. The backlight unit further includes at least a spectrum sensor disposed on the light-exit plane of the backlight unit.

### BACKGROUND OF THE INVENTION

1. Field of the Invention

The invention relates to a backlight unit, and more particularly, to an LED light-mixing package of a backlight unit that produces white light.

2. Description of the Prior Art

LEDs are widely applied as pilot lamps and light sources for various household appliances and instruments. This is due in part to the LEDs advantages, including: a long lifetime, small size, high resistance to earthquakes, low heat emission, and a low consumption of electric power. Additionally, development in recent years has resulted in LEDs that can produce rich color and high brightness. As a result, the LED is further applied in many kinds of movable electronic products. For example, the LED is utilized as a back light source for small-sized displays thereby becoming a source for a stream of illumination light having low power consumption and low contamination (i.e., radiation).

Please refer to FIG. 1. FIG. 1 is a schematic diagram of a section view of an LED element 10 according to the prior art. The prior art LED element 10 comprises a package seat 12 having two electrodes 20, 22 and an LED chip 14 having an N type electrode 16 and a P type electrode 18 corresponding to the electrodes 20, 22. In the process of fabricating the chip type LED element 10, the LED chip 14 is glued on the package seat 12 with silver glue (not shown). After the LED chip 14 is fixed on the package seat 12, a wire bonding process is performed to individually connect the N type electrode 16 and the P type electrode 18 of the LED chip 14 to the electrodes 20, 22 of the package seat 12 through two conductive wires 24, 26. After the wire bonding process, a sealing process is performed. The sealing process begins by setting the entire LED element 10 in a mold (not shown). Next, the mold is filled with epoxy resin or other similar materials and later the LED element 10 is removed from the mold after it hardens. Finally, the LED chip 14, the package seat 12, and all the electrodes and wires are covered in a sealing member 28 that is composed of epoxy resin.

Since a flat display of a general electronic product requires white light from its back light source, an LED serving as a back light must emit white light. However, even with white light LEDs many advantages, including: small sizes, high response speeds, low heat emissions, low consumptions of electric power, long lifetimes, high resistance to earthquakes, and low contamination, and are able to be flat packaged, the technique of developing white light LEDs, when compared to the common tungsten filament lamps or fluorescent lamps is not mature. White light LED production techniques suffer from problems of high fabrication cost and low emission efficiency of the white light LEDs. Therefore, white light LEDs are not commonly used in products.

Conventionally, the process of fabricating white light LED includes the following methods:

(1) Using a blue LED chip together with yellow-green fluorescent powder to produce white light. The cost and efficiency of this method are low, and consequently this is the most common method adopted by manufacturers. However, this method has a significant disadvantage: its white light lacks red lights and has bad color saturation performance.

(2) Utilizing red, blue, and green LED chips together to produce white light by controlling currents of the three LED chips respectively. This method has a high efficiency and high cost.

(3) Using a UV chip together with red, green, and blue fluorescent powder packaged together. This method has low efficiency and UV light easily damages the epoxy resin in the package.

(4) Using a blue LED chip with red and green florescent powder. This method also has a disadvantage that the white light has a low efficiency.

Presently, manufacturers are conducting further research on a method to package a red LED chip, a blue LED chip, and a green LED chip in a single package with epoxy resin, so that the single package can produce red light, blue light, and green light at the same time. However, the light-mixing performance of a conventional epoxy resin is poor. Hence, to improve the light-mixing performance to obtain white light, a light-mixing mechanism is acquired and positioned between the light guide plate and the single package with three kinds of LED chips, or the size of the light guide plate is enlarged to increase a distance between the display area of the display panel and the package.

Please refer to FIG. 2, which is a schematic diagram of the arrangement of a light guide plate and an LED package according to a method for improving light-mixing performance of the prior art. Preferably, an LED package 30 includes a red LED chip, a blue LED chip, and a green LED chip, which is applied to an edge light type back light unit. As shown in FIG. 2, the LED packages 30 are positioned at a side 32a of the light guide plate 32. Since the light-mixing performance is poor, the distance between the LED packages 30 and the display area 34 of the light guide plate 32 must be increased. Therefore, the size of the light guide plate 32 must be enlarged to provide a light-mixing area 36, such that light emitted from the LED package 30 can sufficiently mix in the light-mixing area 36 to produce white light before passing into the display area 34. Accordingly, both of the above-mentioned methods for increasing the length of the light guide plate or positioning a light-mixing mechanism increase the overall size or the cost of the backlight unit.

Hence, the fabrication of an LED package that can efficiently produce white light with low fabrication cost is still an important issue for manufacturers.

### SUMMARY OF THE INVENTION

It is therefore an objective of the present invention to provide a light emitting diode mixing package having different color LED chips and compensation films corresponding to each LED chip, such that the various colors produced by the light emitting diodes can be mixed in the backlight unit to produce white lights, thereby eliminating the need of increasing the size of the light guide plate 66 for generating white light beams as is required by the prior art.

According to the present invention, a backlight unit includes a light guide plate having a light-incidence plane and a light-exit plane and at least a light emitting diode (LED) mixing package disposed in proximity to the light-incidence plane for providing lights, and a spectrum sensor disposed on the light-exit plane of the backlight unit. The light emitting diode mixing package includes at least a first color LED chip and at least a first color compensation film corresponding to the first color LED chip, and at least a second color LED chip and at least a second color compensation film corresponding to the second color LED chip.

Preferably, the present invention matches the red LED chip, blue LED chip, and green LED chip with corresponding cyan compensation film, purple compensation film, and yellow compensation film to form a light emitting diode mixing package. Hence, by utilizing a much shorter light mixing distance, the present invention is able to eliminate the need of increasing the size of the light guide plate for generating white light beams as is required by the conventional technique. Additionally, the backlight unit of the present invention includes a sensor disposed on the light-exit plane of the light guide plate to measure the spectrum produced by the light emitting diode mixing package. Preferably, the present invention is able to utilize the parameters obtained by the sensor to adjust the voltage or electrical current of the backlight unit, thereby maintaining the color uniformity in the display region.

By matching light emitting diodes with corresponding compensation films, the backlight unit of the present invention is able to achieve a much broader color saturation range, and thereby a higher NTSC value than the conventional three color LED backlight units. Moreover, by utilizing the parameters obtained by the sensor to adjust the voltage or electrical current of the backlight unit, the color saturation and distribution can be further adjusted. In other words, the original color saturation (and hence the NTSC value) will rotate, thereby producing a best color output.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a section view of an LED element according to the prior art.

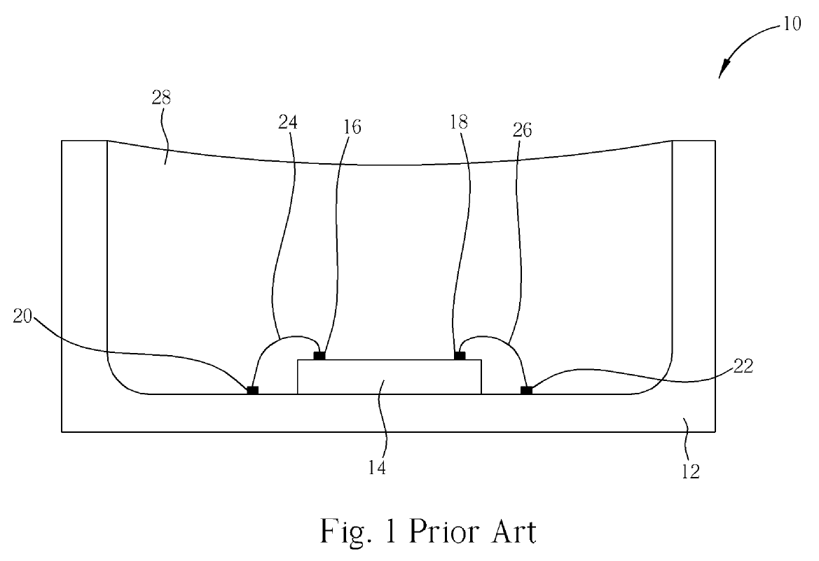

FIG. 2 is a schematic diagram of the arrangement of a light guide plate and an LED package according to the prior art.

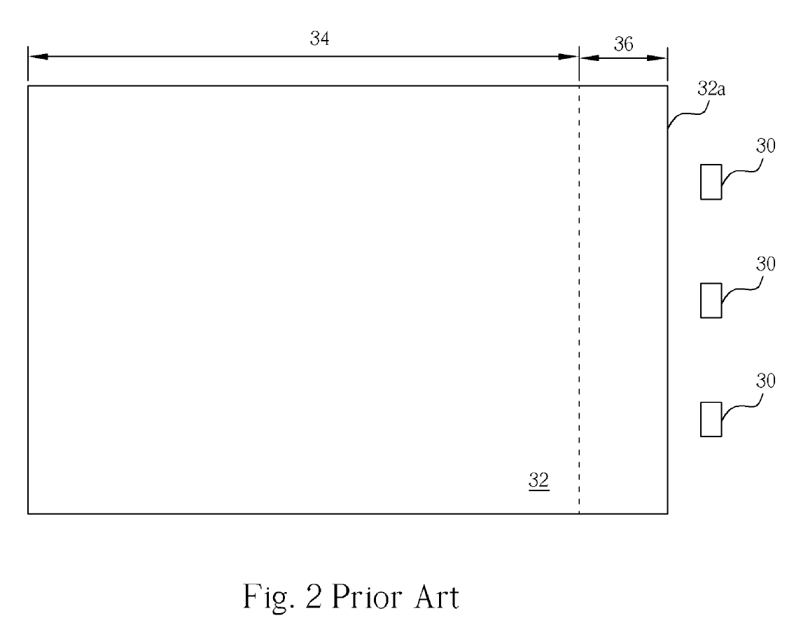

FIG. 3 is a perspective diagram showing the cross-section of a backlight unit according to the present invention.

FIG. 4 is a perspective diagram showing the light emitting diode mixing package of the light guide plate from FIG. 3.

FIG. 5 is a perspective diagram showing the light guide plate, light emitting diode mixing package, and a plurality of sensors according to the present invention.

FIG. 6 is a block diagram showing the means of adjusting the color saturation of a backlight unit according to the present invention.

FIG. 7 is a perspective diagram showing the means of adjusting the color saturation on a CIE coordinates graph according to the present invention.

### DETAILED DESCRIPTION

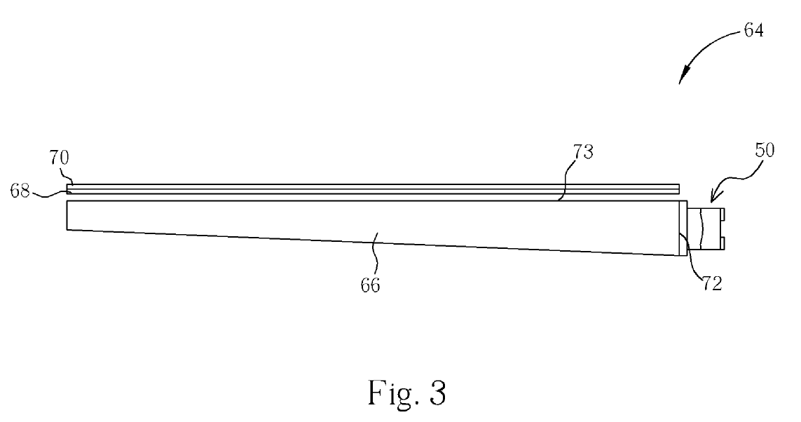

Please refer to FIG. 3. FIG. 3 is a perspective diagram showing the cross-section of a backlight unit 64 according to the present invention. As shown in FIG. 3, the backlight unit 64 includes a transparent light guide plate 66, a plurality of optical films 68 and 70, and at least a light emitting diode mixing package 50 utilized as a light source.

As shown in FIG. 3, one edge of the light guide plate 66 is a light-incidence plane 72, in which the light-incidence plane 72 is utilized for receiving the light generated by the light source. Additionally, a light-exit plane 73 formed on the top surface of the light guide plate 66, and a reflecting layer (not shown) is formed on the surface of the light guide plate 66 that is opposite to the light-incidence plane 72 and opposite to the light-exit plane 73, such that the light entering from the light-incidence plane 72 can only exit through the light-exit plane 73. Moreover, the optical films 68 and 70 disposed on the light-exit plane 73 of the light guide plate 66 are utilized to increase the brightness and uniformity of the light produced. Preferably, the optical films 68 and 70 are diffuser films or prisms.

According to the preferred embodiment of the present invention, the backlight unit 64 is an edge-type backlight unit, in which the light source of the backlight unit 64 is the light emitting diode mixing package 50. Alternatively, the backlight unit 64 can also be a direct-type backlight unit, wherein the light-incidence plane is located on the bottom of the light guide plate. Preferably, the light guide plate 66 is a wedge-shaped plate or a flat plate.

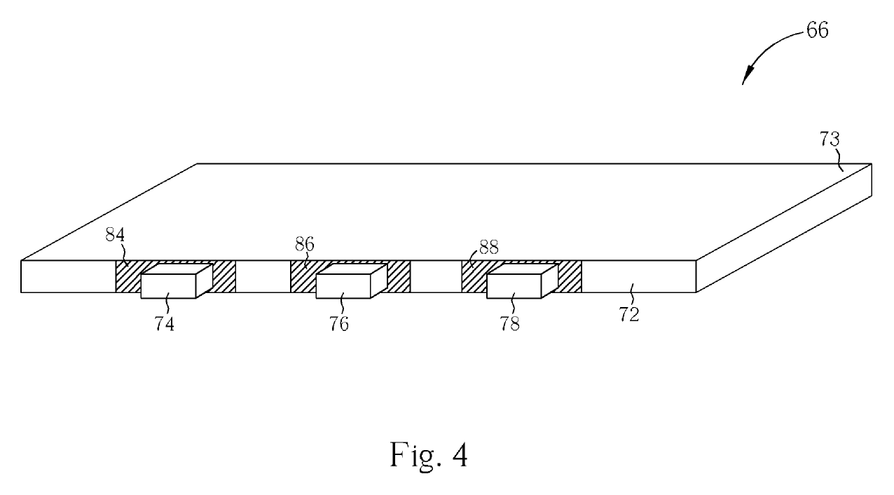

Please refer to FIG. 4. FIG. 4 is a perspective diagram showing the light emitting diode mixing package 50 of the light guide plate 66 from FIG. 3. As shown in FIG. 4, the light emitting diode mixing package 50 is utilized as the light source of the backlight unit 64 of the present invention, in which the light emitting diode mixing package 50 is situated in proximity to the light-incidence plate 72. Preferably, the light emitting diode mixing package 50 includes at least a red LED chip 74, at least a green LED chip 76, and at least a blue LED chip 78, in which the red LED chip 74, the green LED chip 76, and the blue LED chip 78 are utilized to generate red light, green light, and blue light. Additionally, each of the red LED chip 74, the green LED chip 76, and the blue LED chip 78 is connected to the electrodes (not shown) of the backlight unit 66 via a plurality of wires (not shown), in which the LED chips can also be electrically connected to the external wires via the backlight unit 66. Moreover, the light emitting diode mixing package 50 includes at least a cyan compensation film 84 corresponding to the red LED chip 74, at least a purple compensation film 86 corresponding to the green LED chip 76, and at least a yellow compensation film 88 corresponding to the blue LED chip 78, in which the compensation films are disposed on the light-incidence plane 72 of the light guide plate 66. According to the preferred embodiment of the present invention, the cyan compensation film 84, the purple compensation film 86, and the yellow compensation film 88 can be fully transparent compensation films or semi-transparent compensation films.

Preferably, the present invention first matches at least a red LED chip, a blue LED chip, and a green LED chip to compensation films corresponding to each of the LED chips, utilizes the LED chips and compensation films to generate white lights, and projects the white lights into the light-incidence plane 72 of the light guide plate 66, thereby decreasing the light mixing distance of the light emitting diodes and simultaneously eliminating the need of increasing the size of the light guide plate 66 for generating white light beams as is necessary in the prior art.

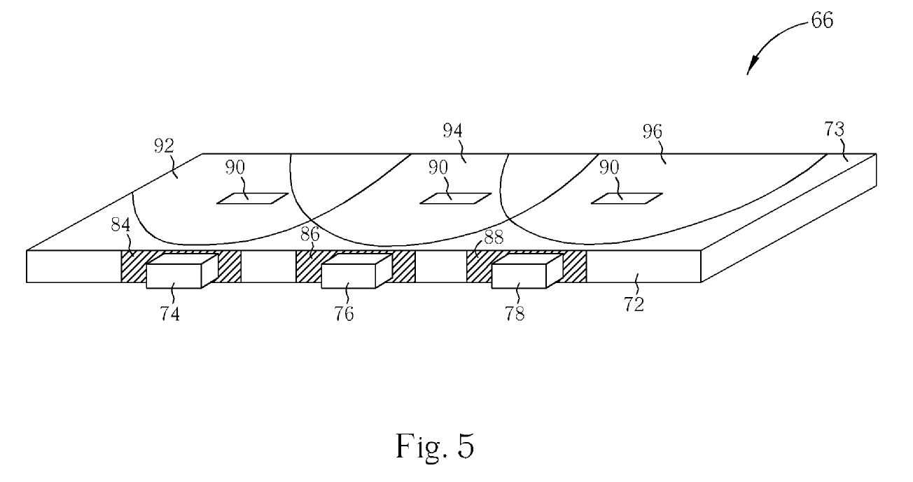

According to the preferred embodiment of the present invention, a sensor 90, such as a spectrum sensor, can be further installed on the surface of the light guide plate 66 to adjust the input current of the color and brightness of the backlight unit 64 after mixing the light via the light emitting diode mixing package 50. Please refer to FIG. 5. FIG. 5 is a perspective diagram showing the light guide plate 66, light emitting diode mixing package 50, and a plurality of sensors 90 according to the present invention. As shown in FIG. 5, since the red LED chip 74, the green LED chip 76, and the blue LED chip 78 produce different light mixing regions 92, 94, and 96 after mixing the light with the corresponding cyan compensation film 84, the purple compensation film 86, and the yellow compensation film 88, the present invention is able to dispose at least a sensor 90 on the light-exit plane 73 of the light guide plate 90, or in each of the light mixing region 92, 94, and 96, as shown in the figure, to detect and measure the spectrum produced on the surface of the backlight unit 64. After the spectrum is detected, the present invention is able to feedback the result to separately adjust the input current or electrical voltage of each light emitting diode, thereby maintaining the color uniformity in the display area and adjusting the color and intensity variation of the backlight unit after light mixing.

Preferably, the wavelengths of a conventional three color LED chip are 590-700 nm for red light, 500-560 nm for green light, and 400-480 nm for blue light. The present invention provides said conventional wavelengths and additionally the backlight unit of the present invention provides the wavelength range of cyan, purple, and yellow from the corresponding compensation films. By matching the red LED chip 74, green LED chip 76, and blue LED chip 78 with the corresponding cyan compensation film 84, purple compensation film 86, and yellow compensation film 88, the backlight unit 64 of the present invention is able to produce significantly improved color uniformity and color saturation as compared to the conventional three color LED backlight unit. Additionally, the color mixing scheme of the present invention can be applied in multi-color LED modules having two colors, four colors, or more.

Preferably, the present invention matches the red LED chip, blue LED chip, and green LED chip with corresponding cyan compensation film, purple compensation film, and yellow compensation film to form a light emitting diode mixing package. Hence, by utilizing a much shorter light mixing distance, the present invention is able to eliminate the need of increasing the size of the light guide plate as is necessary in the prior art for generating white light beams. Additionally, the number, color, and position of the LED chips and compensation films corresponding to the LED chips can be adjusted according to various product design requirements, thereby increasing the light mixing efficiency. Moreover, the backlight unit of the present invention also includes a sensor, such that the sensor is disposed on the light-exit plane of the light guide plate to measure the spectrum produced by the light emitting diode mixing package. Preferably, the present invention is able to utilize the parameters obtained by the sensor to adjust the voltage or electrical current of the backlight unit, thereby maintaining the color uniformity in the display region.

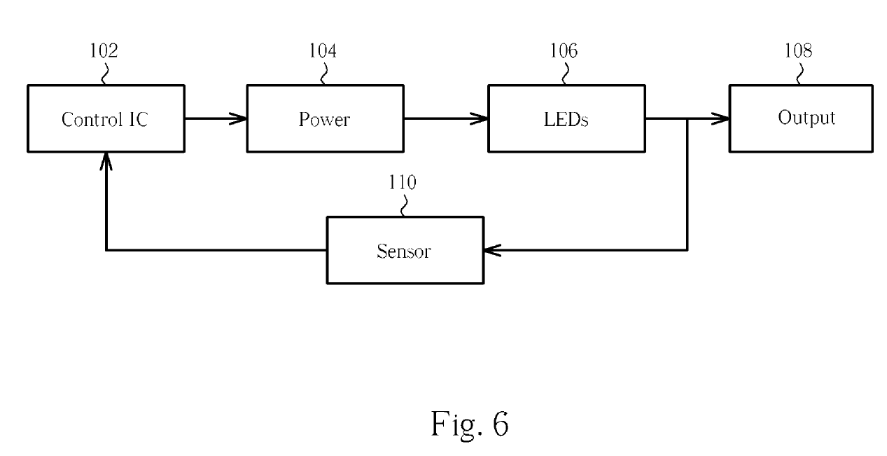

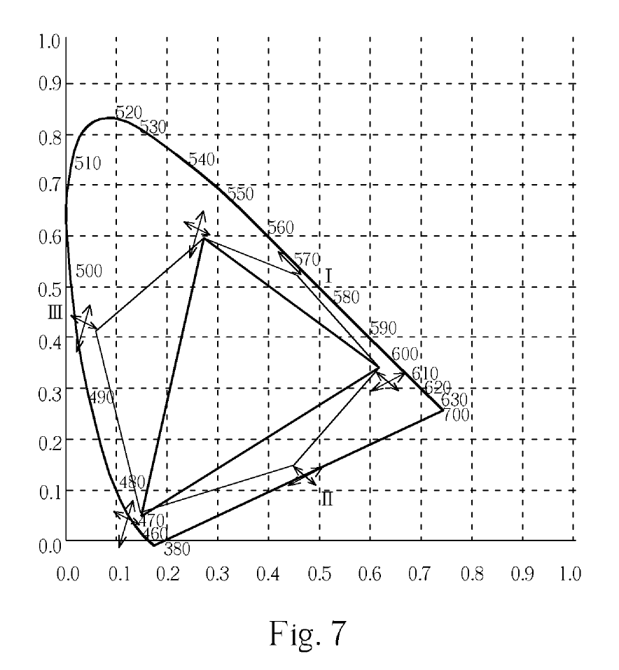

By matching light emitting diodes with corresponding compensation films, the backlight unit of the present invention is able to cover a much broader color saturation range set by the national television system committee (NTSC) than is possible using the conventional three color LED backlight unit, thereby obtaining a significantly higher NTSC value. As shown in FIG. 6, the color hue in the display region can be adjusted by utilizing a control IC 102 and power supply 104 to control the electrical current and voltage of the LEDs 106. Additionally, a sensor 110, described earlier, is utilized to feedback the measured parameters and adjust the saturation distribution of the backlight unit, and eventually pass the result to the output 108. In other words, the original color saturation (and hence the NTSC value) will rotate, as shown in FIG. 7, thereby producing better color output.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A backlight unit comprising:
a light guide plate comprising a light-incidence plane and a light-exit plane; and
at least a light emitting diode (LED) mixing package disposed in proximity to the light-incidence plane for providing lights, the light emitting diode mixing package comprises:
at least a first color LED chip and at least a first color compensation film corresponding to the first color LED chip; and
at least a second color LED chip and at least a second color compensation film corresponding to the second color LED chip; and
a spectrum sensor disposed on the light-exit plane of the backlight unit.

2. The backlight unit of claim 1, wherein the spectrum sensor measures the spectrum produced by the light emitting diode (LED) mixing package.

3. The backlight unit of claim 1 further comprising at least a third color LED chip and at least a third color compensation film corresponding to the third color LED chip.

4. The backlight unit of claim 1, wherein the first color LED chip comprises a red LED chip.

5. The backlight unit of claim 4, wherein the first compensation film comprises a cyan compensation film.

6. The backlight unit of claim 1, wherein the second color LED chip comprises a green LED chip.

7. The backlight unit of claim 6, wherein the second color compensation film comprises a purple compensation film.

8. The backlight unit of claim 3, wherein the third color LED chip comprises a blue LED chip.

9. The backlight unit of claim 8, wherein the third color compensation film comprises a yellow compensation film.

10. The backlight unit of claim 3, wherein the first color compensation film, the second color compensation film, and the third color compensation film are fully transparent compensation film or semi-transparent compensation film.

11. The backlight unit of claim 1 further comprising an optical assembly disposed on the light-exit plane of the backlight unit.

12. The backlight unit of claim 11, wherein the optical assembly comprises at least a diffuser film, at least a prism, or both.

13. The backlight unit of claim 1, wherein the backlight unit is an edge-type backlight unit.

14. The backlight unit of claim 1, wherein the light guide plate comprises a wedge-shaped plate or a flat plate.

15. The backlight unit of claim 1, wherein the backlight unit is a direct-type backlight unit, wherein the bottom of the backlight unit and the top of the light guide plate comprise a light-incidence plane.
